(19) United States
(12) Patent Application Publication
(10) Pub. No.: US 2025/0253136 A1
(43) Pub. Date: Aug. 7, 2025

(54) PLASMA GENERATOR AND COOLING JACKET

(71) Applicant: HORIBA STEC, Co., Ltd., Kyoto-shi (JP)

(72) Inventor: Yoshio WATANABE, Kyoto-shi (JP)

(21) Appl. No.: 19/041,307

(22) Filed: Jan. 30, 2025

(30) Foreign Application Priority Data
Feb. 1, 2024 (JP) 2024-014054
Sep. 11, 2024 (JP) 2024-157247

(51) Int. Cl. H01J 37/32; H01J 37/244

(52) U.S. Cl. CPC H01J 37/32229; H01J 37/244; H01J 37/32275; H01J 2237/002

(57) ABSTRACT

A plasma generator includes: a microwave-generating source that generates a microwave; a cylindrical plasma generation tube through which a gas to be plasmatized by the microwave flows; a waveguide that transmits the microwave to the plasma generation tube; a matching device provided to the waveguide between the microwave-generating source and the plasma generation tube; a cooling jacket that is provided on an outer peripheral surface of the plasma generation tube for cooling; and a cylindrical casing that houses the plasma generation tube and the cooling jacket. The cooling jacket includes: three slits that extend along a traveling direction of the gas flowing through the plasma generation tube, or along a direction inclined with respect to the traveling direction, and through which the microwave passes toward the plasma generation tube; and a cooling channel that is provided between the slits adjacent to each other, and through which a cooling fluid flows.

### CROSS-REFERENCE TO RELATED APPLICATION(S)

The present application is related to, and claims priority to Japanese Patent Application Serial No. 2024-157247, entitled “PLASMA GENERATOR AND COOLING JACKET,” filed on Sep. 11, 2024; and to Japanese Patent Application Serial No. 2024-014054, entitled “PLASMA GENERATOR AND COOLING JACKET,” filed on Feb. 1, 2024, the entire contents of which are incorporated herein by reference.

### BACKGROUND OF THE INVENTION

### Technical Field

The present invention relates to a plasma generator and a cooling jacket.

### Description of the Related Art

Having been conventionally known is a plasma generator that converts a predetermined gas into a plasma state using a microwave, when a process such as machining of a workpiece or thin film formation is to be performed using the gas in the plasma state.

As one example of the plasma generator, there is a plasma generator including a plasma generation tube through which a gas to be plasmatized flows, and a microwave-generating source that generates a microwave for plasmatizing the gas flowing through the plasma generation tube.

In the process of plasmatizing the gas, heat is generated. This heat may cause the plasma generation tube to become heated and damaged. Therefore, some plasma generators of this kind include a cooling jacket for cooling the plasma generation tube, as disclosed in JP 2020-205172 A, for example. Such a cooling jacket has four or more slits provided along the direction in which the gas flowing through the plasma generation tube travels, and through which the microwave emitted from outside of the plasma generation tube passes, and columnar channels that are provided between the adjacent slits and through which a cooling fluid flows. With this configuration, a microwave generated from the microwave-generating source passes through the slits and plasmatizes the gas flowing through the plasma generation tube, while the plasma generation tube is being cooled by the cooling fluid flowing through the columnar channels. In this manner, it is possible to prevent the plasma generation tube from becoming damaged by the heat generated at the time of plasmatization.

### PRIOR ART DOCUMENT

### Patent Document

JP 2020-205172 A

### SUMMARY OF THE INVENTION

Conventionally, it has been believed that the efficiency of the plasma generation can be improved by providing a larger number of slits to the cooling jacket, because the plasma generation tube would have a larger area permitting the microwave to pass.

In a cooling jacket having eight slits, for example, the cooling jacket and the casing have resonance frequency at 4 GHz, as indicated in FIG. 6. Because this resonance frequency is offset from the frequency of the microwave, it takes time to make an adjustment for matching the resonance impedance of the cooling jacket and the casing to that of the microwave-generating source, and this matching adjustment using a matching device has been burdensome.

Therefore, a main object of the present invention is to enable a matching device to operate quickly and to alleviate the burden on the matching device, in a plasma generator that converts a gas into plasma using a microwave.

As a result of intensive studies carried out by the inventors of the present invention, in an attempt to address the issue described above, the inventors have arrived at the present invention on the basis of a first-time finding that, with a cooling jacket with three slits, the cooling jacket and the casing come to have a resonance frequency near the frequency of the microwave.

That is, a plasma generator according to the present invention includes: a microwave-generating source that generates a microwave; a plasma generation tube that has a cylindrical shape and through which a gas to be plasmatized by the microwave flows; a waveguide that connects the microwave-generating source and the plasma generation tube, and transmits the microwave to the plasma generation tube; a matching device provided to the waveguide between the microwave-generating source and the plasma generation tube; a cooling jacket that is provided on an outer peripheral surface of the plasma generation tube and cools the plasma generation tube; and a casing that has a cylindrical shape, and that houses the plasma generation tube and the cooling jacket, in which the cooling jacket includes: three slits that extends along a traveling direction of the gas flowing through the plasma generation tube, or along a direction inclined with respect to the travelling direction, and through which the microwave passes toward the plasma generation tube; and a cooling channel that is provided between the slits adjacent to each other, and through which a cooling fluid for cooling the plasma generation tube flows.

In such a plasma generator, because the cooling jacket has three slits, the resonance frequency of the cooling jacket and the casing is brought near 2.45 GHz. Because the discrepancy between this resonance frequency and the frequency of the microwave is reduced, compared with that in the conventional counterpart, it is possible to reduce the time required in the adjustment for matching the resonance impedance of the cooling jacket and the casing to the impedance of the microwave-generating source, and to alleviate the burden in the matching adjustment using the matching device.

Preferably, the slits extend in or inclined with respect to a direction perpendicular to a direction of an oscillation of an electric field of the microwave; a cross section of the waveguide has a rectangular shape, and a long side of the rectangular shape section extend along or are inclined with respect to a direction in which the slits extend.

With such a configuration, because the slits are provided along the direction perpendicular to the direction of the oscillation of the electric field of the microwave, and the long sides of the rectangular cross section of the waveguide extend along the direction in which the slits extend, the microwave is allowed to pass through the slits efficiently, with less reflections of the microwave on the cooling jacket. In this manner, the plasma generation tube is irradiated appropriately with the microwave, so that the gas flowing inside the plasma generation tube can be plasmatized, efficiently.

Preferably, at least two of the three slits are positioned facing the microwave-generating source.

With such a configuration, because at least two slits are positioned facing the microwave-generating source, the microwave generated by the microwave-generating source is transmitted to the plasma generation tube more efficiently, compared with a configuration in which only one slit faces the microwave-generating source. As a result, the gas flowing inside the plasma generation tube can be plasmatized efficiently.

In order to plasmatize the gas flowing inside the plasma generation tube uniformly along the circumferential direction of the plasma generation tube, the microwave also need to be passed from the opposite side of the microwave-generating source.

Therefore, as one example, the waveguide may further include a reflector that is provided in a manner facing the microwave-generating source, with the plasma generation tube disposed between the reflector and the microwave-generating source, and that is configured to reflect the microwave from the microwave-generating source toward the plasma generation tube; at least one of the three slits is provided in a manner facing the reflector; and at least another one of the slits is provided in a manner facing the microwave-generating source.

With such a configuration, in the cooling jacket having the three slits, one of the slits provided in a manner facing the reflector allows the microwave reflected from the reflector to pass through the plasma generation tube, and another one of the slits allows the microwave generated by the microwave-generating source to pass through toward the plasma generation tube. As a result, the gas flowing inside the plasma generation tube can be plasmatized uniformly along the circumferential direction of the plasma generation tube.

Preferably, the casing includes an observation window for observing an internal condition of the plasma generation tube.

With such a configuration, by providing the casing with an observation window for observing the internal condition of the plasma generation tube, the plasma generated inside the plasma generation tube can be visually recognized through the observation window, for example, or the temperature of the plasma generation tube can be checked by installing a thermometer or the line on the observation window. As a result, it is not only possible to prevent emission of the microwave to the outside, but also to enable observations of the internal condition of the plasma generation tube.

Preferably, the casing is configured to be dividable into a plurality of members.

With such a configuration, because the casing is configured to be dividable into a plurality of members, the casing can be attached, detached, or assembled, more easily.

The plasma generation tube is preferably formed of yttria, yttria-coated quartz, and/or sapphire tube, or a combination thereof.

With such a configuration, it is possible to prevent formation of a byproduct when plasmatized is a gas containing fluorine.

Preferably, the plasma generator further includes a plurality of plasma detection units that is arranged facing each other along a direction in which the slits open, and that detect a light-emission intensity of plasma generated inside the plasma generation tube.

With such a configuration, because the plurality of plasma detection units is arranged facing each other along the direction in which the slits open, the plurality of plasma detection units can detect the light-emission intensity of the plasma generated inside the plasma generation tube through the slits. Because the distribution of the plasma inside the plasma generation tube can be recognized on the basis of the plasma light-emission intensity detected by the plurality of plasma detection units, a user can detect plasma ignition failures from the plasma distribution.

The plasma distribution inside the plasma generation tube has a more prominent bias in the direction in which the gas travels, than that in the direction intersecting with the direction in which the gas travels.

Therefore, it is preferable for the plurality of plasma detection units to be arranged in the direction in which the gas travels.

With such a configuration, because the plurality of plasma detection units is arranged in the direction in which the gas travels, the plasma distribution in the direction more likely to have a prominent bias can be recognized reliably, so that plasma ignition failures can be detected more reliably.

In order to detect plasma ignition failures from the plasma distribution inside the plasma generation tube in the direction in which the gas travels, it is important to detect the plasma light-emission intensity in a central part of the plasma generation tube.

Therefore, the plurality of plasma detection units preferably detects the plasma light-emission intensity in each of an upper part of the plasma generation tube, a central part of the plasma generation tube, and a lower part of the plasma generation tube, along the direction in which the gas travels.

With such a configuration, because at least a part of the plurality of plasma detection units detects the plasma light-emission intensity in the central part of the plasma generation tube, it is possible to detect the plasma ignition failures, more reliably.

Furthermore, because the other plasma detection units detect the plasma light-emission intensities in the upper part and the lower part of the plasma generation tube, it is possible to identify the plasma distribution in the entire plasma generation tube, along the direction in which the gas travels, accurately.

Furthermore, a cooling jacket provided to an outer peripheral surface of a plasma generation tube that has a cylindrical shape and through which a gas to be plasmatized by a microwave flows, and configured to cool the plasma generation tube, the cooling jacket including: three slits that are provided along a traveling direction of the gas flowing through the plasma generation tube, and through which the microwave passes toward the plasma generation tube; and a cooling channel that is provided between the slits that are adjacent to each other, and through which a cooling fluid for cooling the plasma generation tube flows.

With such a configuration, it is possible to achieve the same action and effects as those achieved by the plasma generator described above.

A cooling jacket provided on an outer peripheral surface of a plasma generation tube that has a cylindrical shape and through which a gas to be plasmatized by a microwave flows, and configured to cool the plasma generation tube, the cooling jacket includes: a slit that extends along or in a direction inclined with respect to a direction perpendicular to a direction of an oscillation of an electric field of the microwave, and through which the microwave passes toward the plasma generation tube; and a cooling channel that is provided separately from the slit and through which a cooling fluid for cooling the plasma generation tube flows, in which the slit extends along or in a direction inclined with respect to a direction perpendicular to the direction of the oscillation of the electric field of the microwave; and a cross section of the waveguide has a rectangular shape, and a long side of the rectangular shape extends along or in a direction inclined with respect to a direction in which the slit extends.

With such a configuration, by allowing the microwave to pass through the slit, the plasma generation tube can be irradiated efficiently with the microwave.

According to the present invention configured as described above, in the plasma generator that uses a microwave to plasmatize a gas, it is possible to quickly operate a matching device, and to reduce the burden on the matching device.

### BRIEF DESCRIPTION OF THE DRAWINGS

FIG. 1 is a schematic diagram of a plasma generator according to one embodiment of the present invention;

FIG. 2 is a front view of the plasma generator according to the embodiment;

FIG. 3 is a cross-sectional view taken along line A-A across the plasma generator according to the embodiment;

FIG. 4 is a cross-sectional view taken along line B-B across the plasma generator according to the embodiment;

FIG. 5A is a schematic view with a casing attached, and FIG. 5B is a schematic view with the casing removed, in the embodiment;

FIG. 6 is measurement results indicating a relationship between the number of slits and resonance frequencies;

FIG. 7 is a graph comparing an etching rate of a cooling jacket having three slits, with an etching rate of a cooling jacket having eight slits;

FIGS. 8A to 8D are schematics illustrating cooling jackets with three slits in various modes;

FIG. 9 is a side view of a plasma generator according to another embodiment; and

FIG. 10 is a cross-sectional view taken along line C-C across the plasma generator according to the other embodiment.

### DETAILED DESCRIPTION

A plasma generator according to one embodiment of the present invention will now be explained with reference to some drawings. Note that any of the drawings described below may be schematic representations, with some omissions and exaggerations made as appropriate, to facilitate understanding. The same elements are denoted by the same reference numerals, and the descriptions thereof will be omitted as appropriate.

A plasma generator 100 according to the embodiment is configured to plasmatizes a gas by emitting a microwave to the gas.

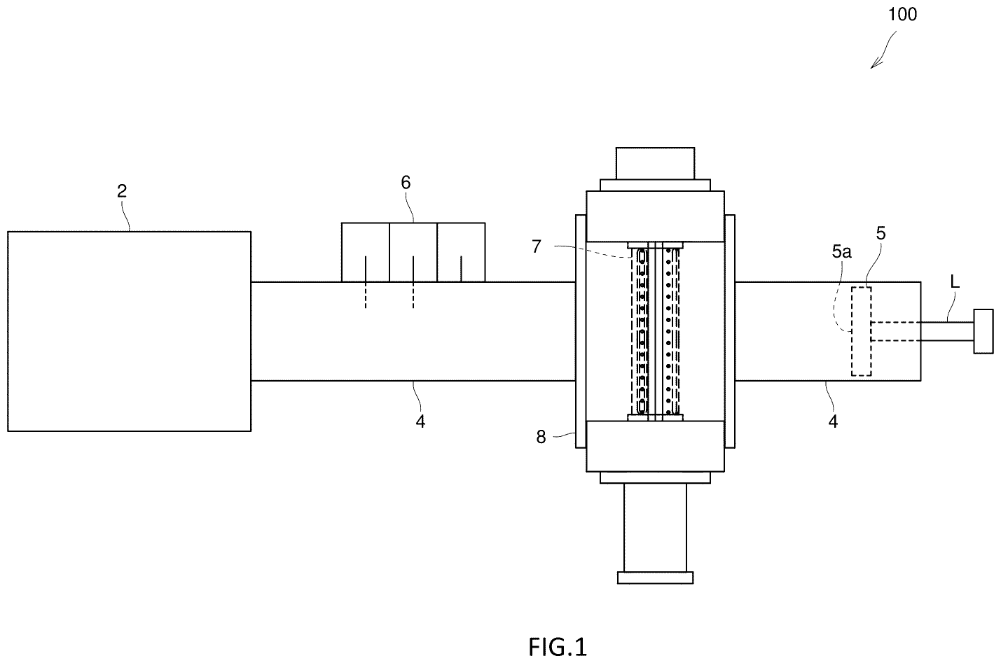

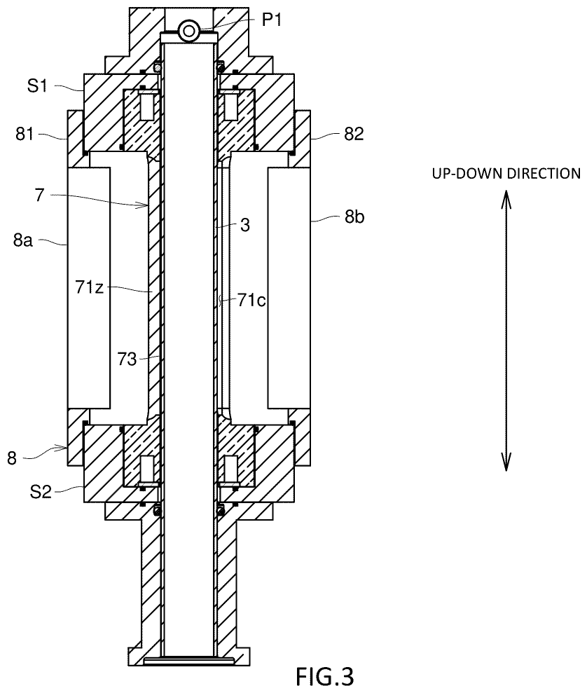

Specifically, as illustrated in FIG. 1 or 3, the plasma generator 100 includes a microwave-generating source 2 that generates a microwave, a plasma generation tube 3 through which a gas to be plasmatized by the microwave flows, a waveguide 4 that transmits the microwave, a reflector 5 that reflects the microwave, a matching device 6 provided to the waveguide 4, a cooling jacket 7 that cools the plasma generation tube 3, and a casing 8 that houses the plasma generation tube 3 and the cooling jacket 7. Each of these components will now be described.

The microwave-generating source 2 generates a microwave for plasmatizing the gas flowing through the plasma generation tube 3. Specifically, the microwave-generating source 2 is formed of, for example, a magnetron. The frequency of the microwave generated from the microwave-generating source 2 is, for example, 300 MHz or higher and 300 GHz or lower (preferably 2.45 GHz). The wavelength of the microwave generated from the microwave-generating source 2 is, for example, 1 mm or more and 1 m or less (preferably 12 cm or so), and the output for the microwave oscillation is, for example, 1 kW or more and 10 kW or less.

The plasma generation tube 3 has a substantially cylindrical shape, and the gas to be plasmatized by the microwave flows therethrough. The plasma generation tube 3 is made of, for example, yttria, but is not limited thereto. For example, without limitation to yttria, the plasma generation tube 3 may be made of yttria-coated quartz and/or sapphire tube, or a combination thereof.

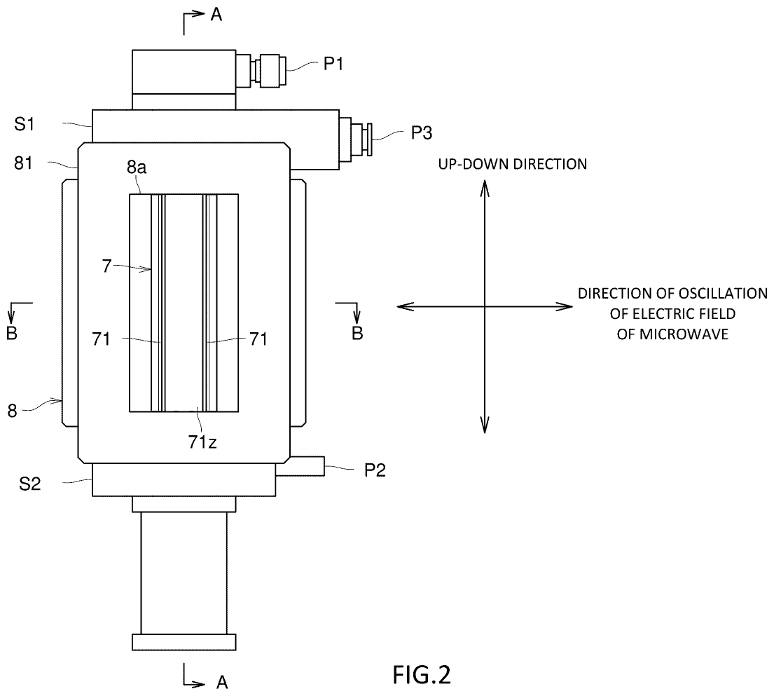

Considering the direction in which the gas flowing through the plasma generation tube 3 as an up-down direction, the upper end of the plasma generation tube 3 is connected to a gas inlet port P1 through which the gas to be plasmatized, supplied by a gas supply source (not illustrated), enters the plasma generation tube 3, as illustrated in FIGS. 2 and 3. The gas supplied through the gas inlet port P1 flows into the plasma generation tube 3, and the plasmatized gas flows out of the plasma generation tube 3 through the lower end thereof, into a processing chamber (not illustrated). In the description hereinafter, it is assumed that the up-down direction corresponds to the direction in which the gas flowing inside the plasma generation tube 3 travels, in the same manner.

A component of the gas supplied from the gas supply source is selected as appropriate, depending on the process to be carried out in the processing chamber (not illustrated). Examples of the components of the gas include SF₆, He, Ar, NF₃, H₂, O₂, N₂, NF₃, Cl₂, HCl, NH₃, CF₄, C₂F₆, C₃F₈, C₄F₈, Cl₃F, N₂O, or H₂O.

The waveguide 4 is, for example, a rectangular waveguide that is hollow and has a quadrangular prism-like shape, and transmits the microwave generated by the microwave-generating source 2 to the plasma generation tube 3. Specifically, the waveguide 4 connects the microwave-generating source 2 to an opening 8a provided to the casing 8 in a manner provided facing the microwave-generating source 2, and extends in a direction orthogonal to the up-down direction.

The waveguide 4 also extends from an opening 8b provided to the casing 8 in a manner facing the opposite side of the microwave-generating source 2, in the direction orthogonal to the up-down direction. Inside the waveguide 4, the reflector 5 is provided. Specifically, the reflector 5 is configured to reflect the microwave generated by the microwave-generating source 2 to the plasma generation tube 3, and has a reflection surface 5a provided in a manner facing the microwave-generating source 2, with the plasma generation tube 3 interposed therebetween.

Connected to a surface on the opposite side of the reflection surface 5a is a rod L that moves the reflector 5 in the direction orthogonal to the up-down direction. By moving the rod L, the position at which the microwave is reflected is controlled. The position at which the microwave is reflected is controlled by an actuator (not illustrated) in such a manner that a stationary wave is formed inside the waveguide 4.

The matching device 6 is provided to the waveguide 4, between the microwave-generating source 2 and the plasma generation tube 3, and performs matching for matching the impedance of the microwave-generating source 2 to the resonance impedance of the cooling jacket 7 and the casing 8. Specifically, the matching device 6 includes a plurality of stubs. Each of such stubs is enabled to adjust the amount by which the stub protrudes into the internal space of the waveguide 4, and by adjusting the position at which the stub protrudes with respect to a reference position, the impedance of the microwave-generating source 2 is matched with the resonance impedance of the cooling jacket 7 and the casing 8.

The cooling jacket 7 is hollow and has a cylindrical shape, and is provided on the outer peripheral surface of the plasma generation tube 3, to cool the plasma generation tube 3. Specifically, as illustrated in FIG. 3, the cooling jacket 7 includes: three slits 71 that extends in the up-down direction and allowing a microwave to pass therethrough to the plasma generation tube 3; cooling channels 72 that are provided between two adjacent slits 71 and through which a cooling fluid for cooling the plasma generation tube 3 flows; and a heat conducting member 73 that are interposed between the cooling channel 72 and the plasma generation tube 3 and that conducts the coolness of the cooling channel 72 to the plasma generation tube 3. An upper part and a lower part of the cooling jacket 7 are supported by an upper support member S1 and a lower support member S2, respectively.

Each of the three slits 71 has a substantially rectangular shape, and penetrates the cooling jacket 7 from the outer peripheral surface to the inner peripheral surface. As used herein, one slit means one slit at the time when the cooling jacket 7 and the casing 8 resonate across a section from the upper end to the lower end of the cooling jacket 7, and, by providing the three slits 71 to the cooling jacket 7, the cooling jacket 7 and the casing 8 are caused to resonate at a frequency near the frequency of the microwave-generating source 2. A frequency near the frequency of the microwave-generating source 2 in the present embodiment means a frequency of 2.25 GHz or higher and 2.65 GHz or lower (more preferably 2.40 GHz or higher and 2.50 GHz or lower) when the frequency of the microwave-generating source 2 is 2.45 GHz. When the frequency of microwave-generating source 2 is not 2.45 GHz, the frequency near the frequency of the microwave-generating source 2 means a frequency 90% or higher and 110% or lower (more preferably 97% or higher and 103% or lower) the frequency of the microwave-generating source 2.

In the present embodiment, the three slits 71 extend from the upper end to the lower end of the cooling jacket 7, and are arranged along the circumferential direction of the cooling jacket 7. Specifically, the electric field of the microwave generated from microwave-generating source 2 oscillates in the direction perpendicular to the up-down direction, and each slit 71 extends in the direction perpendicular to the direction in which the electric field of the microwave oscillates. More specifically, the longitudinal direction of each of the slits 71 extends in parallel with the long sides of the rectangular waveguide 4. Note that the shape of each of the slits 71 is not limited to rectangular, and may also be, for example, any thin and long shape such as an elliptical shape. In the present embodiment, all of the slits 71 have the same shape, but may have shapes that are different from one another, or the slits 71 may have different lengths in the longitudinal direction.

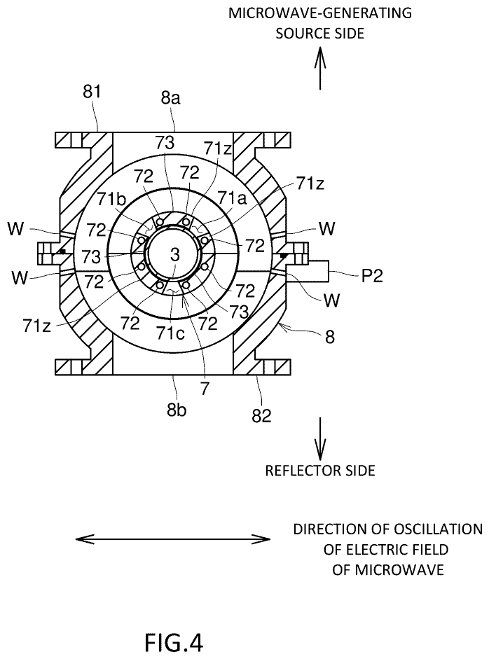

At least two slits 71 among the three slits 71 face the microwave-generating source 2. Specifically, as illustrated in FIG. 4, two slits 71a and 71b, among three slits 71 face the microwave-generating source 2, and the remaining one slit 71c faces the reflection surface 5a of the reflector 5. As a result, the slit 71a and the slit 71b allow the microwave generated from the microwave-generating source 2 to pass directly toward the plasma generation tube 3, and the slit 71c allows the microwave generated from the microwave-generating source 2 to pass toward the plasma generation tube 3 via the reflection surface 5a.

Furthermore, beam-shaped sections 71z in parallel with the slits 71 are provided between the adjacent slits 71, respectively. The beam-shaped sections 71z are provided across the upper end to the lower end of the cooling jacket 7. Inside the beam-shaped sections 71z, cooling channels 72 are provided.

The cooling channels 72 has a substantially columnar shape, and is provided across the upper end to the lower end of the cooling jacket 7 in along the up-down direction. Specifically, the plurality of cooling channels 72 are formed at substantially equal intervals along the circumferential direction of the cooling jacket 7, and, as illustrated in FIG. 4, eight cooling channels 72 are provided in the present embodiment, but the number of cooling channels 72 is not limited to any particular number. In the present embodiment, the cooling channels 72 are provided in all of the beam-shaped sections 71z in order to better cool the plasma generation tube 3, but it is also possible for the cooling channels 72 to be provided to some of the beam-shaped sections 71z.

A cooling fluid inlet port P2 for allowing the cooling fluid to flow into the cooling channels 72 is connected to the lower ends of the cooling channels 72, and a cooling fluid outflow port P3 for allowing the cooling fluid to flow out of the cooling channels 72 is connected to the upper ends of the cooling channels 72. That is, the cooling fluid flows through the cooling channels 72 in the opposite direction of the traveling direction of the gas that flows inside the plasma generation tube 3. Because the plasma generation tube 3 tends to be heated more on the downstream side than on the upstream side of the plasma generation tube 3, because of the plasmatization of the gas. Since the cooling fluid having a lower temperature flows from the lower part of the cooling channel 72, the plasma generation tube 3 can be cooled at a higher efficiency.

The heat conducting member 73 is provided between and in contact with the inner peripheral surface of the beam-shaped sections 71z and the outer peripheral surface of the plasma generation tube 3. In the present embodiment, the heat conducting member 73 is provided across the top end to the bottom end of the cooling jacket 7 in the up-down direction, but it is also possible for the heat conducting member 73 to be provided to a part in the up-down direction. One example of the material forming the heat conducting member 73 is an ultra soft thermally conductive silicone interface pad.

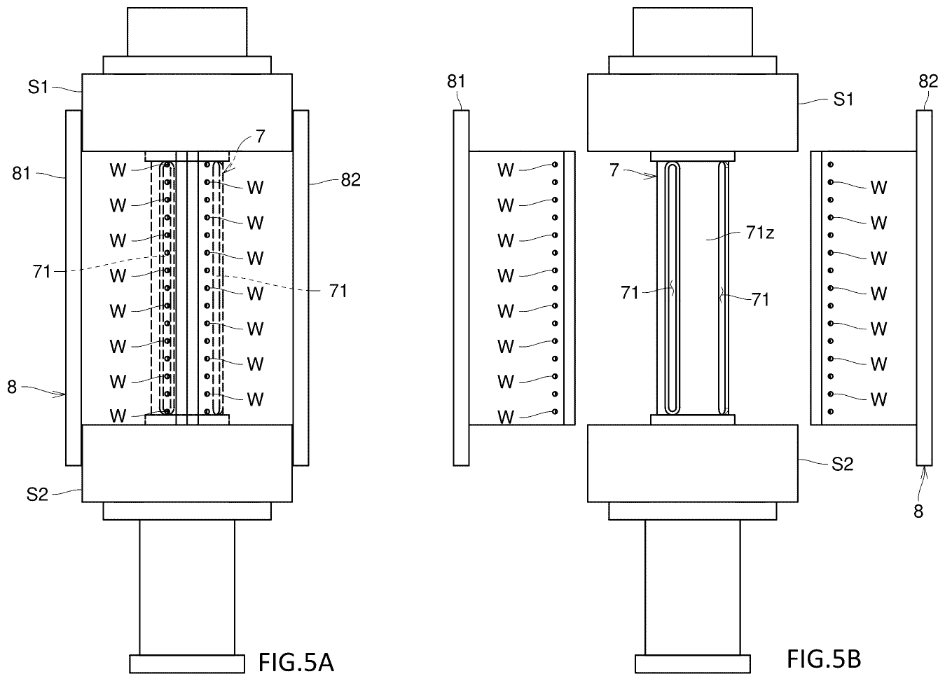

The casing 8 has a substantially tubular shape, and houses the plasma generation tube 3 and the cooling jacket 7 so as to block the emission of the microwaves to the outside. The casing 8 is configured to be dividable into a plurality of members. In the present embodiment, as illustrated in FIGS. 5A and 5B, the casing 8 is configured to be dividable into two members of a first half body 81 and a second half body 82 each having a substantially semi-cylindrical shape, along the up-down direction. Specifically, as illustrated in FIG. 5A, by fixing the first half body 81 and the second half body 82 in a manner holding the plasma generation tube 3 and the cooling jacket 7 between the first half body 81 and the second half body 82, the plasma generation tube 3 and the cooling jacket 7 are housed inside the casing 8. The casing 8 is removed by separating the first half body 81 and the second half body 82 along the up-down direction, as illustrated in FIG. 5B.

The first half body 81 has the opening 8a that opens toward microwave-generating source 2, and that is connected to the waveguide 4. The second half body 82 has the opening 8b that opens toward the reflector 5, and that is connected to the waveguide 4.

The casing 8 is also provided with an observation window W for observing the internal condition of the plasma generation tube 3. Specifically, the observation window W is a through hole provided in a manner penetrating the casing 8, from the outer peripheral surface to the inner peripheral surface thereof. In the present embodiment, a plurality of observation windows W is provided along the up-down direction of the casing 8. More specifically, each of the first half body 81 and the second half body 82 is provided with the plurality of observation windows W at substantially equal intervals from the upper part to the lower part thereof. Note that the number of observation windows W and the positions of the observation windows W are not limited to any number nor to any particular positions.

The present invention will now be described more specifically with reference to an example. The present invention is not limited by the following example, and it is needless to say that the example may be modified as appropriate within a scope in which the gist, which is to be described later, can be met, and all of such modifications fall within the technical scope of the present invention.

### Example: Comparison in Resonance Frequency

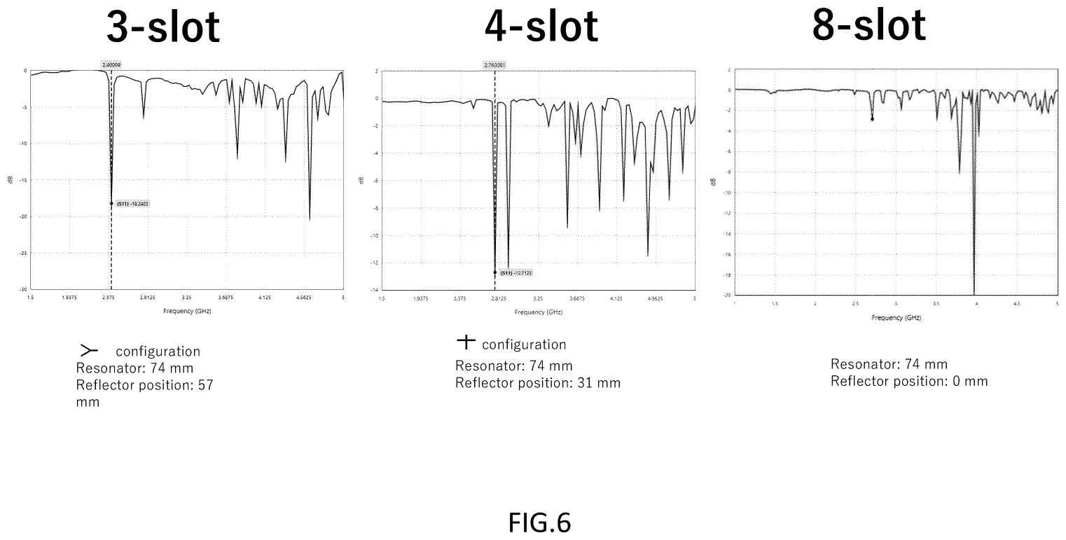

Measurement results indicating a comparison between the resonance frequency of the cooling jacket and the casing having the three slits, with the resonance frequencies of the cooling jackets and the casings having other numbers of slits will now be described with reference to FIG. 6.

In this example, the resonance frequencies of cooling jackets and casings with three and eight slits were measured using a network analyzer.

As a result of the measurements, it was confirmed that, with the cooling jacket having three slits, the resonance frequency of the cooling jacket and the casing was 2.40 GHz. By contrast, with the cooling jacket having four slits, it was confirmed that the resonance frequency of the cooling jacket and the casing was around 2.76 GHz. With the cooling jacket having eight slits, it was confirmed that the resonance frequency of the cooling jacket and the casing was around 4.00 GHz. It can be expected that, with the cooling jacket having one or two slits, the resonance frequency of the cooling jacket and the casing will be lower than 2.40 GHz, which is the resonance frequency of the cooling jacket having three slits. With the cooling jacket having the three slits, because the resonance frequency of the cooling jacket and the casing deviates least from 2.45 GHz that is the frequency of the microwave, as compared with the cooling jackets having the other numbers of slits, it is possible to alleviate the burden of matching adjustment that uses the matching device.

### Example: Comparison in Etching Rate

Using the plasma generator having a cooling jacket with three slits, and the plasma generator having a cooling jacket with eight slits, a gas for etching a wafer (etching gas) was supplied into the plasma generation tube of each, and the plasma generation tube was irradiated with a microwave (at a frequency of 2.45 GHz) to plasmatize the etching gas flowing through the plasma generation tube. The microwave was applied in such a manner that the direction of oscillation of the electric field was set perpendicularly to the height direction of the plasma generation tube (the length direction of the slits). A wafer was then etched with the plasmatized gas, and the etching rate was measured under the following four conditions.

Condition 1: An etching gas pressure of 100 Pa; etching gas components of SF6 and O2 at concentrations of 1400 sccm and 400 sccm, respectively; and a microwave output of 1000 W.

Condition 2: An etching gas pressure of 200 Pa; etching gas components of SF6 and O2 at concentrations of 1400 sccm and 400 sccm, respectively; and a microwave output of 1000 W.

Condition 3: An etching gas pressure of 100 Pa; an etching gas component of SF6 at a concentrations of 1400 sccm; and a microwave output of 1000 W.

Condition 4: An etching gas pressure of 100 Pa; etching gas components of SF6 and O2 at concentrations of 1400 sccm and 400 sccm, respectively; and a microwave output of 500 W.

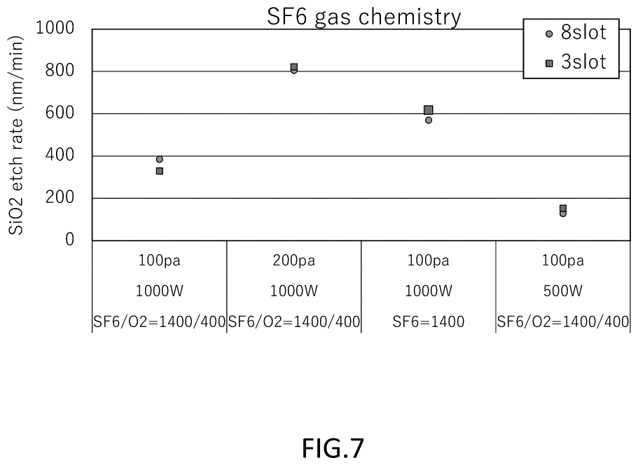

FIG. 7 is a graph of etching rates achieved by etching the wafer under the four conditions described above, using the cooling jackets having three slits and eight slits.

In Condition 1, the etching rate achieved by the plasma generator including the cooling jacket having three slits was 330.1 nm/min, and the etching rate achieved by the plasma generator including the cooling jacket having eight slits was 385.5 nm/min.

In Condition 2, the etching rate achieved by the plasma generator including the cooling jacket having three slits was 822.0 nm/min, and the etching rate achieved by the plasma generator including the cooling jacket having eight slits was 805.8 nm/min.

In Condition 3, the etching rate achieved by the plasma generator including the cooling jacket having three slits was 617.0 nm/min, and the etching rate achieved by the plasma generator including the cooling jacket having eight slits was 570.0 nm/min.

In Condition 4, the etching rate achieved by the plasma generator including the cooling jacket having three slits was 153.3 nm/min, and the etching rate achieved by the plasma generator including the cooling jacket having eight slits was 129.0 nm/min.

Although it was originally expected that the etching rate would increase by increasing the number of slits on the cooling jacket, it was found out that there was not much difference in the etching rate between the cooling jackets with three slits and the eight slits in any of Conditions 1 to 4, and it was confirmed that even the plasma generator having a cooling jacket with three slits is capable of generating plasma efficiently.

### Advantageous Effects Achieved by Embodiment

With the plasma generator 100 according to the present embodiment, because the cooling jacket 7 has the three slits 71, the cooling jacket 7 and the casing 8 have a resonance frequency near 2.45 GHz. Because there is less discrepancy between the resonance frequency and the frequency of the microwave, compared with those of the cooling jackets having the other numbers of slits, it is possible to reduce the time required in the adjustment for matching the resonance impedance of the cooling jacket 7 and the casing 8, to the impedance of the microwave-generating source 2, and to alleviate the burden in the matching adjustment using the matching device 6.

In addition, because there is not much difference between the etching rates of the cooling jackets with the three slits and the eight slits, even the plasma generator having a cooling jacket with three slits is capable of generating plasma efficiently.

Furthermore, because the slits 71 are provided along the direction perpendicular to the direction of the oscillation of the electric field of the microwave, and the long sides of the rectangular cross section of the waveguide 4 extend along the direction in which the slits 71 extend, the microwave is allowed to pass through the slits 71 efficiently, with less reflections of the microwave on the cooling jacket 7. In this manner, because the plasma generation tube 3 is irradiated appropriately with the microwave, the gas flowing inside the plasma generation tube 3 can be plasmatized efficiently.

Furthermore, because at least two slits 71a and 71b are positioned facing the microwave-generating source 2, the microwave generated by the microwave-generating source 2 is transmitted to the plasma generation tube 3 more efficiently, compared with a configuration in which only one slit faces the microwave-generating source 2. As a result, the gas flowing inside the plasma generation tube 3 can be plasmatized efficiently.

Moreover, because the one slit 71c is provided in a manner facing the reflector 5, the gas flowing inside can be plasmatized uniformly in the circumferential direction of the plasma generation tube 3.

Furthermore, it is possible to visually recognize the plasma generated inside the plasma generation tube 3 through the observation window W, or to check the temperature inside of the plasma generation tube 3 by inserting a thermometer such as an optical fiber thermometer into the observation window W. As a result, it is not only possible to prevent emission of the microwave to the outside, but also to make observations of the internal condition of the plasma generation tube 3.

Furthermore, because the casing 8 is configured to be dividable into a plurality of members, the casing 8 can be easily attached and detached.

Furthermore, because the plasma generation tube 3 is made of yttria, it is possible to prevent generation of a byproduct when the gas to be plasmatized contains fluorine.

### OTHER EMBODIMENTS

Note that the present invention is not limited to the embodiments described above.

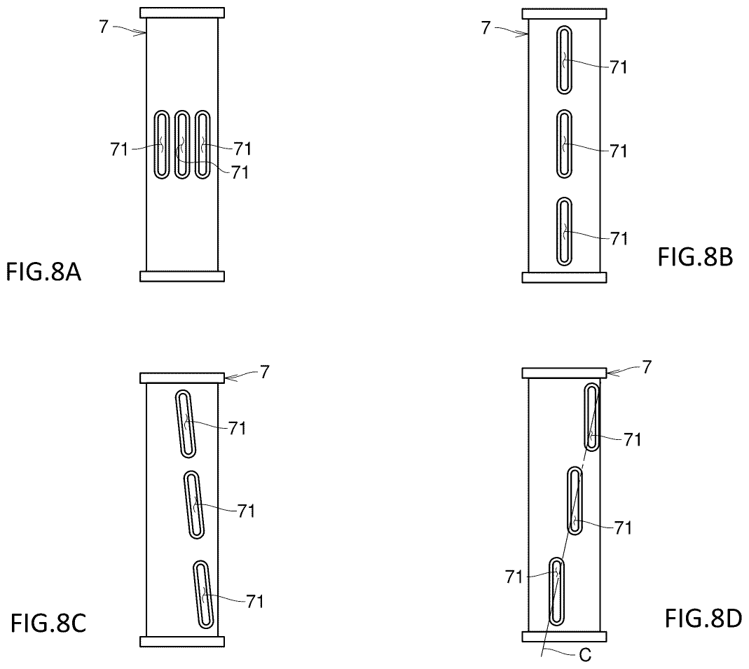

In the configuration according to the embodiment described above, when the three slits 71 are provided across the upper end to the lower end of the cooling jacket 7 and arranged along the circumferential direction of the cooling jacket 7, and the cooling jacket 7 and the casing 8 resonate near the frequency of the microwave-generating source 2, one slit 71 may be divided into a plurality, in the manner illustrated in FIGS. 8B to 8D.

For example, as illustrated in FIG. 8B, one slit 71 may have a longitudinal component along the up-down direction, and may be divided into a plurality, along the up-down direction. As illustrated in FIG. 8C, the one slit 71 may have a longitudinal component inclined with respect to the up-down direction, and may be divided into a plurality of portions along the inclined longitudinal direction component. Furthermore, for example, as illustrated in FIG. 8D, one slit 71 may be provided along a general virtual straight line C that is inclined with respect to the up-down direction, and may be divided into a plurality of parts along the general virtual straight line C. In the configuration illustrated in FIG. 8D, the slit 71 divided into a plurality has a longitudinal component along the up-down direction.

In the embodiment described above, the three slits 71 are provided across the upper end to the lower end of the cooling jacket 7, but the present invention is not limited thereto. For example, in the example of FIG. 8A, when each of the slits 71 is provided across the upper end to a part of the lower end of the cooling jacket 7, and the cooling jacket 7 and the casing 8 resonate each other, three slits 71 are provided.

In this case, for example, as illustrated in FIG. 8B, the three slits 71 each may have a longitudinal direction component along the up-down direction, and arranged along a generally straight line that is in parallel with the longitudinal direction component of the slit 71. Furthermore, for example, as illustrated in FIG. 8C, the three slits 71 each may have a longitudinal direction component inclined with respect to the up-down direction, and arranged along a generally straight line parallel with the longitudinal direction component of the slit 71. Furthermore, for example, as illustrated in FIG. 8D, the three slits 71 each may have a longitudinal component in the up-down direction, and arranged along a general virtual line C that is inclined with respect to the up-down direction.

In the embodiment described above, the slits 71 are provided in such a manner that the longitudinal directions thereof are perpendicular to the direction of the oscillation of the electric field of the microwave. However, the slits 71 may include the up-down direction as a longitudinal component. That is, the longitudinal direction of the slit 71 may be inclined with respect to the direction perpendicular to the direction of the oscillation of the electric field of the microwave.

In the embodiment described above, the two slits 71a and 71b are positioned facing the microwave-generating source 2, but the direction where each of the slits 71 faces is not limited thereto. For example, all of the three slits 71 may be positioned facing the microwave-generating source 2, or one slit 71 may be positioned facing the microwave-generating source 2.

In the embodiment described above, the plasma generator 100 includes the reflector 5, but it is also possible for the plasma generator 100 not to include the reflector 5.

In the embodiment described above, the casing 8 has the observation window W, but it is also possible for the casing 8 not to have the observation window W.

In the embodiment described above, the casing 8 is dividable into two members of the first half body 81 and the second half body 82, but may also be dividable into three or more members, or may be integrated as one unit. Although the casing 8 is configured dividable along the up-down direction, the direction in which the casing 8 is dividable is not limited to the up-down direction, and may be dividable, for example, in a direction orthogonal to the up-down direction or any other directions.

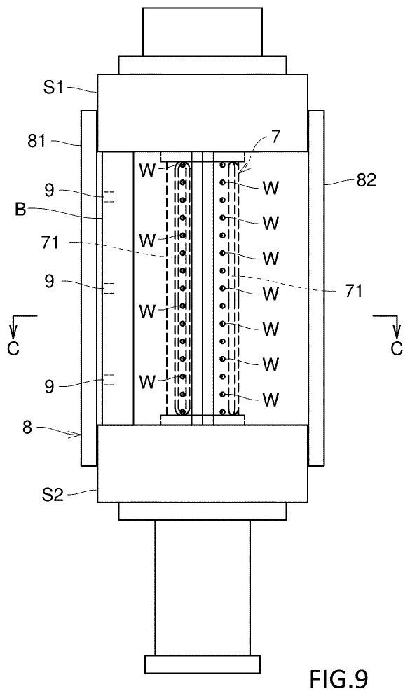

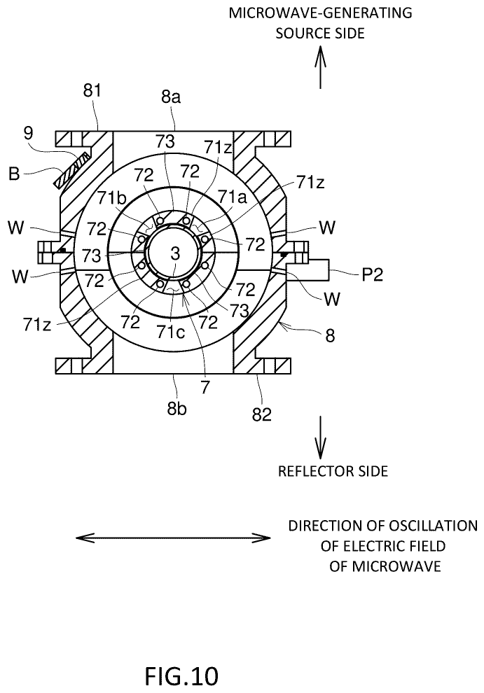

Furthermore, as illustrated in FIGS. 9 and 10, the plasma generator 100 may include a plurality of plasma detection units 9 that detects the light-emission intensity of the plasma generated inside the plasma generation tube 3. At this time, the plurality of plasma detection units 9 is arranged in a manner facing the direction in which the slits 71 open. More specifically, the plurality of plasma detection units 9 is provided on the outer peripheral surface of the casing 8 via an attachment member B having a longitudinal component in the up-down direction.

Each of the plasma detection units 9 detects the plasma light-emission intensity in a predetermined section inside the plasma generation tube 3 through the slits 71. The plasma detection unit 9 is, for example, a photodiode, and outputs an analog signal corresponding to the plasma light-emission intensity to a computing device (not illustrated). The plasma detection unit 9 may include a filter so as to enable detections of a plasma light-emission intensity at a predetermined wavelength.

The computing device is a computer including a CPU, an internal memory, an input/output interface, and the like, and may perform A/D conversion of analog signals obtained by the plasma detection units 9. The computing device may display a plasma distribution on a display unit (not illustrated), such as a display, in real time.

In the example herein, the plurality of plasma detection units 9 is arranged along the up-down direction of the plasma generation tube 3, that is, along the traveling direction of the gas, as illustrated in FIG. 9. In the example herein, the plurality of plasma detection units 9 is arranged along the direction in which one of the slits 71 opening toward the microwave-generating source 2 extends, as illustrated in FIGS. 9 and 10. In order to detect the plasma distribution in the direction intersecting with the traveling direction of the gas, the plurality of plasma detection units 9 may be arranged in a manner facing the two slits 71 that open toward the microwave-generating source 2.

The plurality of plasma detection units 9 detect the light-emission intensities of plasma in sections that are different from one another inside the plasma generation tube 3. Specifically, as illustrated in FIG. 9, the three plasma detection units 9 detect the light-emission intensities of the plasma in the upper part of the plasma generation tube 3, the central part of the plasma generation tube 3, and the lower part of the plasma generation tube 3, respectively, along the traveling direction of the gas. In order to detect the plasma distribution more accurately, at least one plasma detection unit 9 may detect the plasma light-emission intensity in the central part of the plasma generation tube 3. The number of plasma detection units 9 may be at least two or more, and is not limited to three.

In addition, various modifications and combinations of the embodiments are still possible within the scope not deviating from the gist of the present invention.

According to the present invention, in a plasma generator that uses a microwave to plasmatize a gas, it is possible to quickly operate a matching device, and to alleviate the burden on the matching device.

### REFERENCE CHARACTERS LIST

100 plasma generator
2 microwave-generating source
3 plasma generation tube
4 waveguide
5 reflector
6 matching device
7 cooling jacket
71 slit
71z beam-shaped section
72 cooling channel
73 heat conducting member
8 casing
81 first half body
82 second half body
9 plasma detection unit
W observation window

What is claimed is:

1. A plasma generator comprising:
a microwave-generating source that generates a microwave;
a plasma generation tube that has a cylindrical shape and through which a gas to be plasmatized by the microwave flows;
a waveguide that transmits the microwave generated by the microwave-generating source to the plasma generation tube; a matching device provided to the waveguide between the microwave-generating source and the plasma generation tube;
a cooling jacket that is provided on an outer peripheral surface of the plasma generation tube and cools the plasma generation tube; and
a casing that has a cylindrical shape, and that houses the plasma generation tube and the cooling jacket,
wherein the cooling jacket includes:
three slits that extends along a traveling direction of the gas flowing through the plasma generation tube, or along a direction inclined with respect to the travelling direction, and through which the microwave passes toward the plasma generation tube; and
a cooling channel that is provided between the slits adjacent to each other, and through which a cooling fluid for cooling the plasma generation tube flows.

2. The plasma generator according to claim 1, wherein
the slits extend along or in a direction inclined with respect to a direction perpendicular to the direction of oscillation of the electric field of the microwave, and
a cross section of the waveguide has a rectangular shape, and a long side of the rectangular shape extends along or in a direction inclined with respect to a direction in which the slit extends.

3. The plasma generator according to claim 1, wherein at least two of the three slits are positioned facing the microwave-generating source.

4. The plasma generator according to claim 1, further comprising a reflector that is provided in the waveguide, in a manner facing the microwave-generating source, with the plasma generation tube disposed between the reflector and the microwave-generating source, and that is configured to reflect the microwave from the microwave-generating source toward the plasma generation tube,
wherein at least one of the three slits is provided in a manner facing the reflector, and
at least another one of the slits is provided in a manner facing the microwave-generating source.

5. The plasma generator according to claim 1, wherein the casing includes an observation window for observing an internal condition of the plasma generation tube.

6. The plasma generator according to claim 5, wherein the casing is configured to be dividable into a plurality of members.

7. The plasma generator according to claim 1, wherein the plasma generation tube is formed of yttria, yttria-coated quartz, and/or sapphire tube, or a combination thereof.

8. The plasma generator according to claim 1, further comprising a plurality of plasma detection units that is arranged facing each other along a direction in which the slits open, and that detect a light-emission intensity of plasma generated inside the plasma generation tube.

9. The plasma generator according to claim 8, wherein the plurality of plasma detection units is arranged in the direction in which the gas travels.

10. The plasma generator according to claim 9, wherein the plurality of plasma detection units detects the plasma light-emission intensity in each of an upper part of the plasma generation tube, a central part of the plasma generation tube, and a lower part of the plasma generation tube, along the direction in which the gas travels.

11. A cooling jacket provided to an outer peripheral surface of a plasma generation tube that has a cylindrical shape and through which a gas to be plasmatized by a microwave flows, and configured to cool the plasma generation tube, the cooling jacket comprising:
three slits that are provided along or in a manner inclined with respect to a traveling direction of the gas flowing through the plasma generation tube, and through which the microwave passes toward the plasma generation tube; and
a cooling channel that is provided between the slits that are adjacent to each other, and through which a cooling fluid for cooling the plasma generation tube flows.

12. A cooling jacket provided on an outer peripheral surface of a plasma generation tube that has a cylindrical shape and through which a gas to be plasmatized by a microwave flows, and configured to cool the plasma generation tube, the cooling jacket comprising:
a slit that extends along or in a direction inclined with respect to a direction perpendicular to a direction of an oscillation of an electric field of the microwave, and through which the microwave passes toward the plasma generation tube; and
a cooling channel that is provided separately from the slit and through which a cooling fluid for cooling the plasma generation tube flows,
wherein
a cross section of the waveguide has a rectangular shape, and a long side of the rectangular shape extends along or in a direction inclined with respect to a direction in which the slit extends.
